(19) United States
(12) Patent Application Publication
(10) Pub. No.: US 2010/0009270 A1
(43) Pub. Date: Jan. 14, 2010

(54) METHOD FOR OPTIMIZING THE LAYOUT OF AT LEAST ONE TRANSFER DEVICE FOR PRODUCTION OF A DIRECT OR INDIRECT STRUCTURE

(75) Inventor: Joerg Thiele, Vaterstetten (DE)

Correspondence Address: VIERING, JENTSCHURA & PARTNER, 3770 HIGHLAND AVE., SUITE 203, MANHATTAN BEACH, CA, 90266, US

(73) Assignee: Qimonda AG, Munich (DE)

(21) Appl. No.: 12/413,629

(22) Filed: Mar. 30, 2009

(30) Foreign Application Priority Data
Mar. 29, 2008 (DE) 102008016266.3

(51) Int. Cl. G03F 1/00; G06F 17/50

(52) U.S. Cl. 430/5; 716/21; 716/19

(57) ABSTRACT

Embodiments of the invention include a method for generating a model layout for the manufacturing of a transfer device, the method including:
providing transfer structures associated to reference structures and the transfer structures representing structures to be directly or indirectly generated on the substrate;
generating images from the transfer structures using transfer functions;
superimposing the images, thereby generating a candidate model layout;
determining as to whether the candidate model layout fulfills a predefined criterion; and
using the candidate model layout as the model layout in case the predefined criterion is fulfilled.

### CROSS-REFERENCE TO RELATED APPLICATION

This application claims priority to German Patent Application Serial No. 10 2008 016 266.3, which was filed Mar. 29, 2008, and is incorporated herein by reference in its entirety.

### TECHNICAL FIELD

Embodiments of the invention include a method for optimizing a layout of at least one transfer device, and more specifically of a photolithographic mask. With the help of such transfer devices structures of a reference layout are transferred to a substrate to produce direct and indirect structures on the substrate. Thereby, a layout of the transfer facility is optimized in respect to better accuracy to size and also accuracy of size of the directly and indirectly produced structures is optimized.

### BACKGROUND

Microstructures are used in a lot of technical applications. These are structures with dimensions of less than on 1 μm. Such structures are well known for instance by the micro-electronic or the micro-systems technology. The components of the microelectronic state of the art integrated circuits already have structures of below 0.4 μm. The production of such small structures is a continuous challenge for the micro-technology, particularly because conventional manufacturing methods approach their limits. Today further miniaturization is partially only possible by utilization of specific effects. In photolithography, for instance, methods as double-patterning or pitch-fragmentation are used to produce semiconductor structures with width far beyond the theoretically possible resolution of the radiation used.

Because of the high number and partially high complexity of the necessary production steps for production of microstructures there is a high sensitivity against distortions for the up-to-date production method. Also, small irregularities in single process steps may result in exponentially growing distortions of the produced structures when compared to the specification. If the dimensional accuracy of a microstructure of an end product is not ensured, that means if at the respective structure the deviation of the actual size from the nominal dimension increases above an acceptable value then malfunction may result out of this for the respective component. Specially with critical components having only a small manufacturing tolerance, such a malfunction may lead to impracticality of the end product what results in a degradation of the yield of the manufacturing process. To achieve a high yield, a high precision has to be ensured during the complete manufacturing process. Particularly, measures have to be taken to reduce irregularity errors with critical microstructures as much as possible.

A possible approach to improve the dimensional accuracy of structures which are produce by a transfer facility is the optimization of the produced transfer pattern of the respective transfer device. To improve the results of the photolithography, for instance, simulations are used and with the help of simulations the optical imaging property of the photolithographic mask and the used mask structures can be accessed and optimized. Here, data correction methods as for instance optical proximity correction (OPC) are used, by which single mask structures can be changed geometrically in such a way that the imaging properties are improved. However, these data correction methods take into account only such structures which are directly imaged to the substrate.

For methods as double-patterning or pitch-fragmentation, by which the resulting layout of one level of an integrated circuit is divided into different parts and is imaged by the help of different masks in different sub-steps the overall image results after combination of all parts by suitable process steps. Particularly, processes may be applied here which images a part of the layout directly and other parts of the layout result from derived indirect pattern and indirect patterning processes. According to an embodiment of the invention, the overall layout image is first combined in an intermediate layer and subsequently with the help of this layer converted to the final structure, for instance, to an electrical relevant device. The plurality of the process steps necessary thereto generally involves specific non-linearities (which will be named and represented here by a “transfer function”) for the manufacturing. These transfer functions may take effect differently for the different parts of structures which may result in that the final combined structure may partially result in a tremendous deviation from the specification.

In case of double or multiple exposure, the mask may be corrected by the help of the OPC method. Thereby, the correction is merely the addition of the intensity of the aerial image and hence, it relates only to the sum of the structures which emerge by the transfer of the individual parts in the same photo layer.

An improved method for optimizing the layout within the framework of production of microstructures, especially of integrated circuits, is desired.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows first method steps of a first cycle of the method, whereby, starting from a transfer pattern, an image of a direct and an indirect structure is generated;

FIG. 2 shows further method steps of the first cycle of the method, whereby, by combination of the images, a model layout is generated, which shows a big deviation from the reference layout;

FIG. 3 shows first method steps of a second cycle of the method, whereby the images are generated, now starting from a corrected transfer pattern;

FIG. 4 shows further method steps of the second cycle of the method, whereby, by means of the corrected transfer pattern generated image, an improved model layout is generated, whose deviation from the reference layout is within the tolerance;

FIG. 5 shows method steps of a first cycle of the method, whereby two transfer patterns are optimized at the same time, whereby, starting from the first transfer pattern, images of a first direct structure and a first indirect structure are generated, and whereby, starting from the second transfer pattern, an image of a second direct structure is generated;

FIG. 6 shows further method steps of a first cycle of the described method of FIG. 5, whereby, by combination of the images, a model layout is generated that shows a big deviation from the reference layout;

FIG. 7 shows first method steps of a second cycle of the method shown in FIGS. 5 and 6, whereby the images, now starting from two corrected transfer patterns, are generated;

FIG. 8 shows further method steps of the second cycle of the method shown in FIG. 5-7, whereby an improved model layout is generated from the generated image by means of the corrected first transfer pattern whose deviation from the reference layout is within the tolerance;

FIG. 9 shows a flow chart for clarification of the method according to an embodiment of the invention;

FIG. 10 shows a photolithographic mask with a first transfer pattern, whereby the mask structures are formed as trenches;

FIG. 11 shows an alternative first photolithographic mask with a first transfer pattern, whereby the mask structures are formed as elevations;

FIG. 12 shows a second photolithographic mask with a second transfer pattern, whereby the mask structures are formed as trenches;

FIG. 13 shows a substrate with directly and indirectly generated structures;

FIG. 14 schematically shows an apparatus for performing of the method; and

FIG. 15 schematically shows a system for production of transfer facilities.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments of the invention include a method for improving the dimensional accuracy of structures which are produced according to the requirement of a reference layout. Thereby, the reference layout includes a first reference pattern with a first reference structure which is used as a target for a direct to be produced first structure on a substrate, whereby, by means of the first reference pattern, a first transfer pattern for a first transfer facility is produced which is dedicated for transfer of the first transfer pattern to the substrate for direct production of the first structure. The reference layout further includes a second reference pattern with a second reference structure which is used as a target for a second structure to be indirectly produced on the substrate by deduction from the first structure. It is intended that the first transfer pattern is optimized in such a way that the deviation of the first structure from the first reference structure is reduced. Further, the first transfer pattern is also optimized in such a way that a deviation of the second structure from the second reference structure is reduced. As a result, the dimensional accuracy of a directly as well as the indirectly produced structure is improved.

According to an embodiment of the invention the production of the second structure includes a combination of the first and a third structure. Thereby, a second transfer pattern for a second transfer device is used to also produce a third structure on the substrate. Again, the second transfer pattern is optimized in such a way that a deviation of the second structure from the second reference structure is reduced. By this, the dimensional accuracy also of such indirect structures may be optimized which are produced by the help of a method as, for instance double-patterning or pitch-fragmentation, by the combination of the structures of different masks. Especially, it is possible to tune the optimization of the individual mask in such a way that the optimum is achieved for all structures concerned.

According to an embodiment of the invention, the optimization of the transfer pattern is supported by a computer, whereby a first transfer function is applied to the first transfer pattern to produce a first image. Subsequently, a second transfer function is applied to the first image to produce a second image. From the first and the second image a model layout is produce which includes a first and a second model structure. Subsequently, the first model structure with the first reference structure and the second model structure with the second reference structure are compared. The first transfer pattern will be corrected and the production of the model pattern with the modified transfer pattern is repeated if at least one of the two model structures has a deviation from the respective reference structure which is beyond a predefined tolerance. The optimization of the first transfer pattern will be finalized at that moment as the determined deviation between the model structure and the respective reference structure for all model structures is within the tolerance. By the use of computers, the optimization process of the pattern can be automated. This in turn results in a precise and cost-effective optimization of even complex layouts. By usage of appropriate processing power different variations of the production process, but also of the optimization process may be examined within a relatively short time frame. This allows an easier identification of a plurality of appropriate optimization results as well as the comparison of these solutions with each other. Each of the transfer functions used here may as well describe single process steps of the production as a multitude of such single process steps. For the last case, the used transfer function may include multiple single transfer functions which respectively describe different process steps of the manufacturing process.

A further embodiment of the invention includes that the generation of the model layout includes the combination of the first and the second image as well as the application of a final transfer function to this combination. With the help of the final transfer function also such changes of the involved structures can be described which are caused after the combination of the individual structures on the substrate, for instance, by further process steps.

An embodiment of the invention includes that a fifth transfer function is applied to the second transfer pattern to produce a third image and that for generation of the model layout the third transfer function is applied to the combination of the first, the second and the third image. With the help of the fifth transfer function changes during the transfer of the second transfer pattern to the substrate may be accounted for.

A further embodiment of the invention includes that the optimization of the transfer pattern is iterative, whereby at each iteration step at least one of the transfer patterns is corrected in such a way that at least for one model structure which is produced by its help the deviation of its respective reference structure is reduced. By the usage of a iterative optimization process, the optimization is carried out stepwise, whereby each modification of a transfer pattern, respectively a transfer structure, can be judged to what extent it contributed to the improvement of the overall result. The iterative approach hence permits particularly good optimization results.

According to another embodiment of the invention, a fourth transfer function is applied to the first image before it is combined with the other images. With the help of the fourth transfer function also such changes may be accounted for which effect the first structure generated on the substrate during the deduction of the second structure.

According to an embodiment of the invention, at least one of the optimized model layouts resulting from the transfer patterns is used as layout resulting from the patterns for a photolithographic mask for transfer of the respective transfer patterns to the substrate, whereby the respective transfer pattern is corrected with the help of an OPC method. By including of the OPC method into the described optimization process the structures themselves and also the optical effects produced by the modification of the structures can be accounted for in a better way.

According to another embodiment of the invention, each of the transfer patterns is optimized in such a way that for all directly and indirectly generated model structures the smallest averaged deviation of the respective reference structure is achieved. By this approach, it is possible to assure that the error for the entire substrate is approximately evenly distributed. Furthermore, it can be achieved by this that the dimensional accuracy is optimized only with a specific part of the layout, for instance only with such structures for which a deviation is specially critical. With the help of a cost function it is possible to determine to what extent the deviation error of this part of the layout can be reduced at the expense of such parts of the layout for which the deviation from the specification is less critical.

According to another embodiment of the invention, the optimization of the transfer pattern is conducted within the scope of a double-patterning or pitch-fragmentation method. By this method, the final structures are generated with the help of a plurality of photolithography steps that are independent from each other. According to the invention, during the optimization the method allows to take into account also such structures which are generated by the combination of the direct transfer structures by the help of the different photo masks. By this, it is possible to approach a balanced error distribution with all directly and indirectly generated structures of the entire layout.

Below, an optimization method for layout structures of a binary photo mask is described in more detail. Such masks are used amongst others for the manufacturing of integrated circuits. In principle, the methods described here can be used also for optimization of the layout of other structure transfer devices. For instance, the layout of a photolithographic phase shift mask may be optimized by these methods. Furthermore, the method described here may be used also for optimization of the layout of a stamp for the so-called soft-print lithography by means of which structures are generated on a substrate.

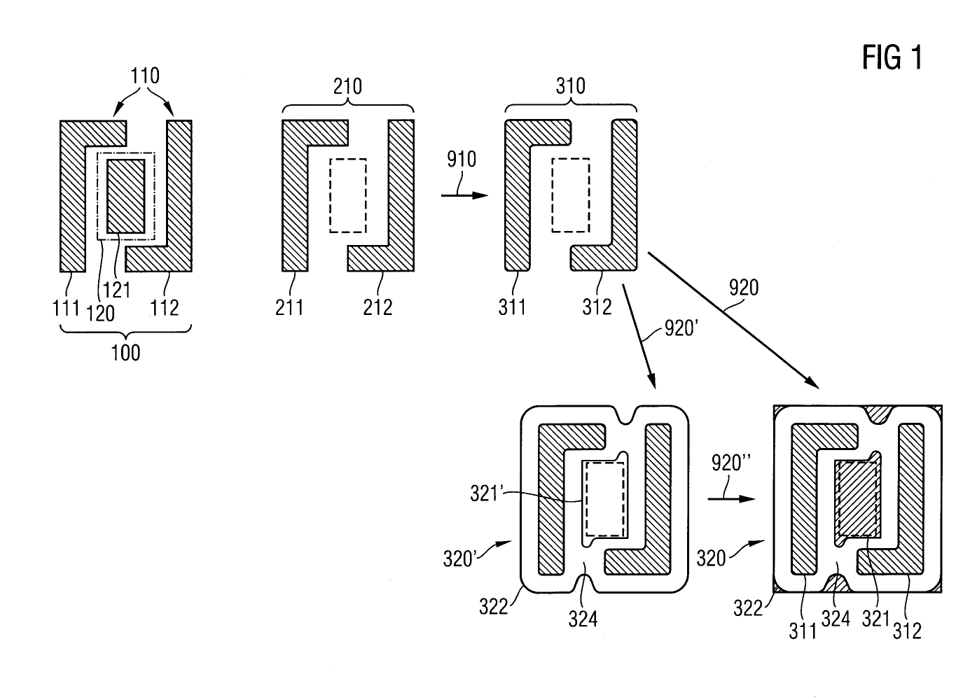

FIG. 1 shows, as an example, the original reference layout as it is used for instance for manufacturing integrated circuits. The reference layout 100 is typically generated by a CAD-supported layout design process and is available for the following optimization- and manufacturing process for usage as a reference layout. For this example, the reference layout 100 includes three simple reference structures 111, 112, 121 which might serve, for instance, as master for the manufacturing of components of an integrated circuit. The two L-shaped reference structures 111, 112, which for instance represent two conductor structures, enclose a rectangular reference structure 121, which for instance represents an active area or alternatively a further conducting structure. The two reference structures 111, 112 shall be imaged directly to the substrate using a photolithographic step, and for the generation of the reference structure 121 an indirect manufacturing method shall be used. Thereby, the structure information from this reference structure 121 is not transferred in a photolithographic step to the substrate, but it is deduced from the already generated reference structures 111, 112 on the substrate and by this structured indirectly. The generation of the reference structure 121 then takes place e.g. in a self-adjusted process.

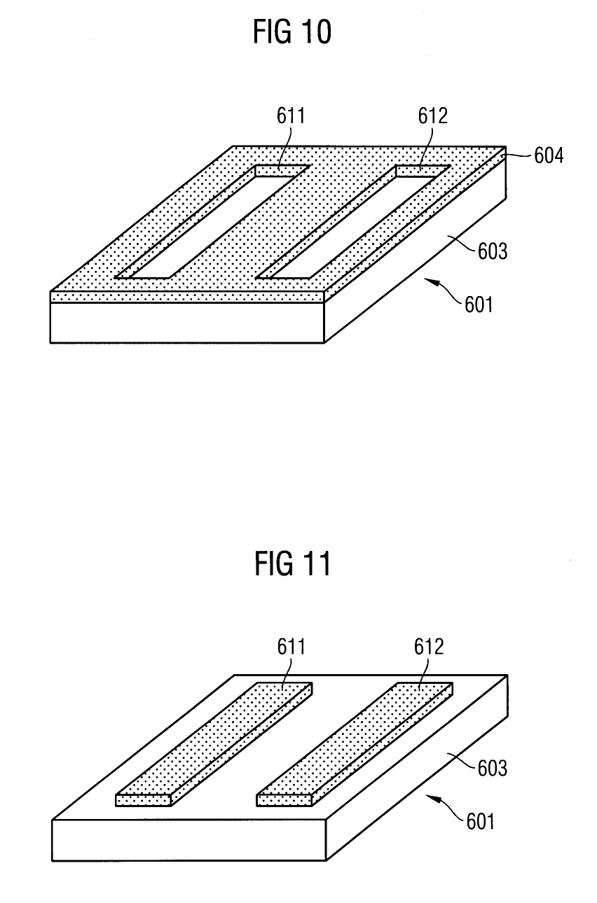

The two L-shaped reference structures 111, 112 hence are assigned to a first reference pattern 110, which is used as master for the first transfer pattern 210. This transfer pattern here serves as a pattern for a respective photo mask 601 (FIG. 10), by whose help the first reference structures 111, 112 are transferred to the substrate. On the other hand, the second reference structure 121 is assigned to a second reference pattern 120, which is indicated by an interrupted dotted line.

For evaluation of the suitability of the first transfer pattern 210 for the real manufacturing process of the integrated circuit, the manufacturing of the reference structures 111, 112 e.g. the conducting structures as well as of the reference structure 121 e.g. an active area is replicated in a simulation environment with the help of the first reference pattern 110. For this a first transfer function 910 is applied to both first transfer structures 211, 212 resulting from the reference structures 111, 112, starting from the first transfer pattern 210, which describes changes of both reference structures 111, 112 and describing the changes of both reference structures 111, 112 by means of the photolithographic imaging process. The first transfer function 910 includes, amongst others, optical effects as for instance diffraction effects, which result in the known imaging errors. In this example, the usage of the first transfer function 910 to the first transfer pattern 210 results in a first image 310, for which the corners of both image structures 311, 312, opposite to the original transfer structures 211, 212, are round off. Depending on the application, the first transfer function 910 may describe also other optical effects as well as changes of the structures during further processing. This includes for instance changes during transfer of the structures from the photo-resist to the substrate for instance by etching of the substrate or by deposition of a material in the respective areas.

For this example, the two image structures 311, 312 represent two conductor structures generated by deposition of an electrical conducting material, which are defined in the regions by the photolithographic process. Now, the self-adjusted generation of the reference structure 121 as e.g. an active area is simulated by means of the first image 310. For this, a second transfer function 920 is applied to the first image 310 to generate a second image 320. The second transfer function 920 includes the description of the forming of an auxiliary structure 322 around the directly generated transfer structures 211, 212 as e.g. the conductor structures 711, 712 (FIG. 13) as well as the generation of the transfer structure 212 as e.g. an active area in the area 321′, defined by means of the auxiliary structure 322. The auxiliary structure, which serves as a spacer for the subsequent self-adjusting process here, may be generated for instance by deposition of a material, by oxidation, by formation of polymers, or by another appropriate process. The generation of the active area may also be generated by a suitable process as for instance the deposition of a material or by ion implantation. For clarification of the method, the method step 920 in FIG. 1 is split in two partial steps 920′ and 920″. The first sub step 920′ includes the generation of an auxiliary structure 322 by deposition of a material around both transfer structures 311, 312 (e.g. conductor structures). Thereby, an opening 321′ is defined in the middle of both transfer structures 311, 312, in which in the second sub-step 920″ an additional material is deposited.

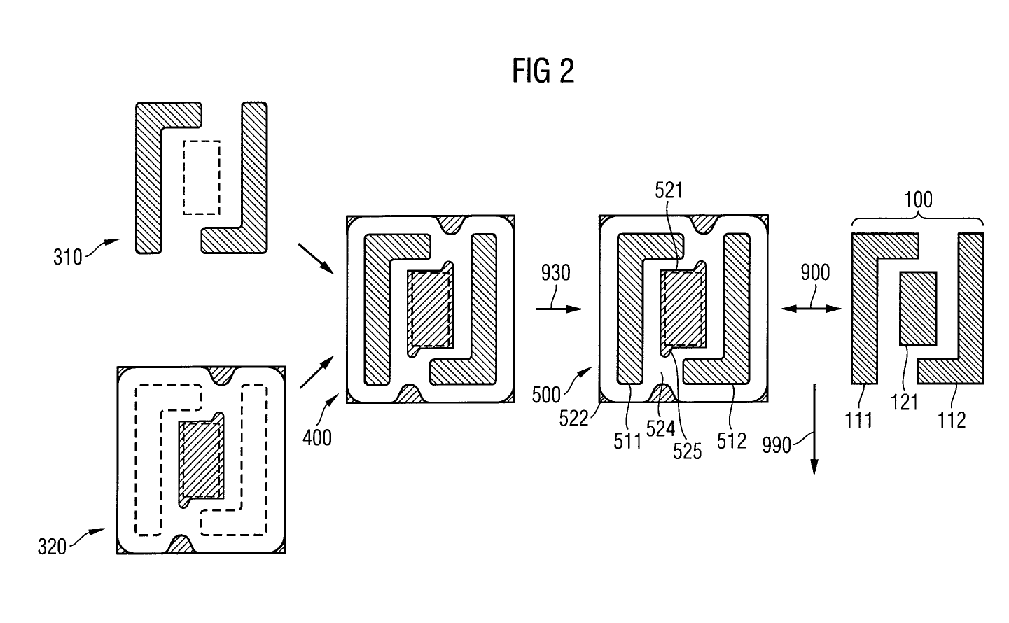

Further in the simulation process, an overall image 400 is generated by the combination of the two images 310, 320. This is shown in FIG. 2. The overall image 400 represents the sum of the directly generated transfer structures 211, 212, also shown in FIG. 13 as directly generated structures 711, 712 on the substrate and the second transfer structure 212, also shown as indirect generated structure 721 (see FIG. 13), which is generated there from by deduction of the direct generated structures. By application of a final transfer function 930, the overall image 400 is finally transformed into the final model layout 500. The final transfer function may thereby describe all changes, which take effect on the structures after their generation on the substrate 702 (FIG. 13). For instance, the generation of the final structure may require that the structures of the overall image is transferred by the help of an etching process to the layers, which lie beyond. In this case, the final transfer function 930 may for instance describe a typical reduction of the breadth of the shown structures of the overall image 400 by an etching process.

The completed candidate model layout 500 will subsequently be compared with the original reference layout 100 to determine possible deviations of the model structures 511, 512, 521 generated by the simulation from the specified reference structures 111, 112, 121. It turns out that particularly the second model structure 521 deviates strongly from the second reference structure 121. Whereas the first model structures 511, 512 are established satisfactorily to a large extent the second model structure 521 shows two unwanted appendices 325, 525, which are caused by the constrictions 324, 524, which are generated during the deposition of the auxiliary structure 322, 522. Because in this example the equal distribution of the deviation error throughout the overall layout is an important quality characteristic, the candidate model layout 500, which is generated by the simulation, fails the validation included in the optimization process 900 what results in that the actual transfer pattern 210 is classified as not satisfactory and that is why it will be further optimized.

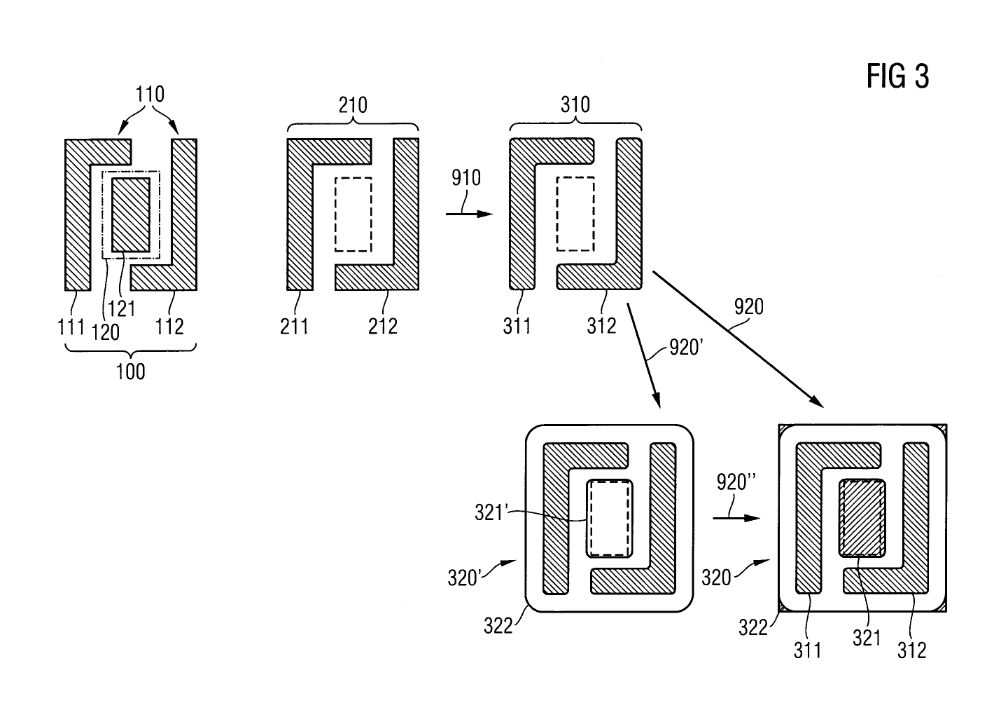

FIG. 3 shows the first transfer pattern 210 after its optimization. As can be recognized by comparison with the reference layout 100, the optimization of the first transfer pattern 210 resulted in a modification of the two direct transfer structures 211, 212 to decrease the distance of the two L-shaped structures 211, 212. Thereby, the short side of the L-shaped structure 211, 212 were each extended up to a virtual extension of the vertical outline drawn as a dashed line of the indirect structure. To verify to what extent the modification of the two structures 211, 212 contributes to an improvement of the overall result, the candidate model layout 500 is generated in a second simulation run this time by means of the corrected transfer structures 211, 212. For this, the first transfer function 911 is applied to the modified transfer structures 211, 212 to generate a modified first image 310. By means of the first image 310 an again modified second image 320 is generated by application of the second transfer function 920. As shown in FIG. 1, due to the extension of the short side of the first transfer structures 211, 212 it results that during the generation of the auxiliary structure 322 in sub step 920′ no constriction 324 is generated anymore. By this the opening 321′ at the inside of the auxiliary structure 322 shows an essentially rectangular form. Therefore, an essentially rectangular second image structure 321 is generated by means of the filling of the opening 321′, which is described by an corresponding transfer function 920″.

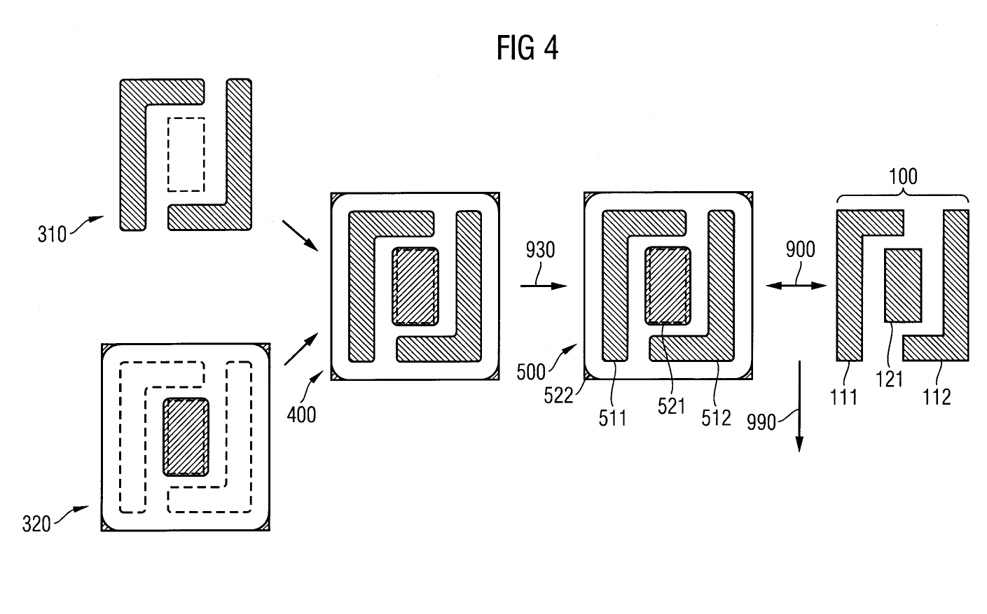

As is shown in FIG. 4, the two images 310, 320 are subsequently combined with each other to obtain an overall image 400 of the structures. By the application of the final transfer function 930, this combination 400 is transferred to a new candidate model layout 500, which is considerably different to the model layout 500 of the first run of FIG. 2. By means of the modification of the first transfer structures 211, 212 during the optimization of the first transfer pattern 210, the appendices 525 of the second model structure 521 have vanished. The second model structure 521 of the optimized model layout 500 is essentially rectangular shaped by this and shows only small deformation.

During an iterated comparison of the optimized model layout 500 with the reference layout 100 it turns out that the match of the second model structure 521 with the corresponding second reference structure 121 was considerably improved by the optimization of the transfer pattern 210. However, the deviation of the two model structures 511, 512 of the corresponding reference structures 111, 112 was higher as in the first run because of the modification of the two first transfer structures 211, 212.

Despite of the still remaining deviation the current model layout 500 this candidate model layout 500 apparently shows the better match with the reference layout 100. In case that the validation of the candidate model layout 500 shows that the deviation of the model structures 511, 512, 521 compared to the respective reference structures 111, 112, 121 and the corresponding transfer structures 211, 212, 221 or the final model layout 500, respectively, compared to the reference layout 100 is within a predefined tolerance, the optimization of the transfer pattern 210 may be finalized. Otherwise, a new optimization of the transfer pattern 210 may take place whereby the transfer structures or parts thereof, respectively, may again be modified and by means of the corrected transfer structures 211, 212, 221 a further model layout 500 which represents a new candidate for the model layout 500 is generated in a repeated simulation step.

At hand the layout validation included in the optimization process 900 rendered that the generated candidate model layout 500, which was generated by means of the optimized transfer layout i.e. the optimized transfer patterns, is satisfactory because the deviation error of the individual model structures 511, 512, 521 is distributed comparatively even throughout the final model layout 500. And so, the optimization method is finalized which is indicated in FIG. 4 by a corresponding arrow 990.

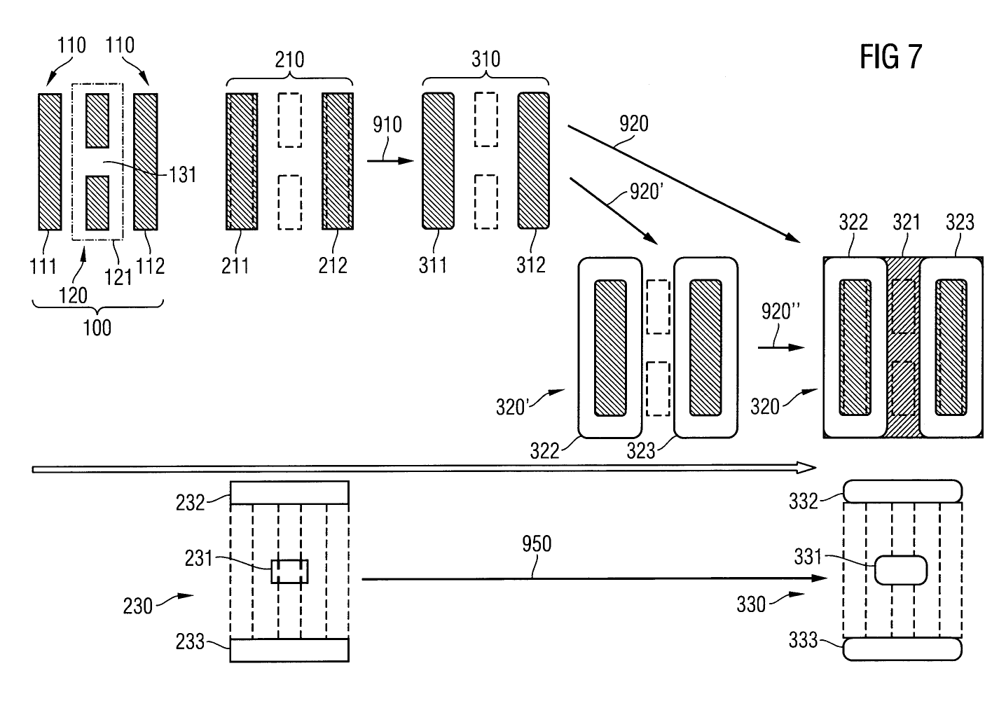

For the exemplary method shown here only one transfer mask for generation of e.g. the structures 711, 712, 721 shown in FIG. 13 is used for the sake of simplicity, but it is also possible to convert the reference layout 100 by means of two or more masks into e.g. corresponding structures 711, 712, 721. The two L-shaped reference structures 111, 112 for instance may be assigned in the course of a double-patterning method each to different transfer patterns 210, 230 (FIG. 7) and be transferred in two separate steps to the substrate. Both processes may be simulated by separate images and joined not before the combination of the images to the overall structure. For simulation of e.g. the indirect generated structure 721 (FIG. 13) the images of the separately simulated structures 711, 712 may be combined with each other to take into account also such effects, which appear by the mutual influence of the two structures 711, 712. By this, in the current case, the bridge 524 (FIG. 2) and by this also the undesirable appendix 525 (FIG. 2) of the indirect structure 521 may be simulated more easily.

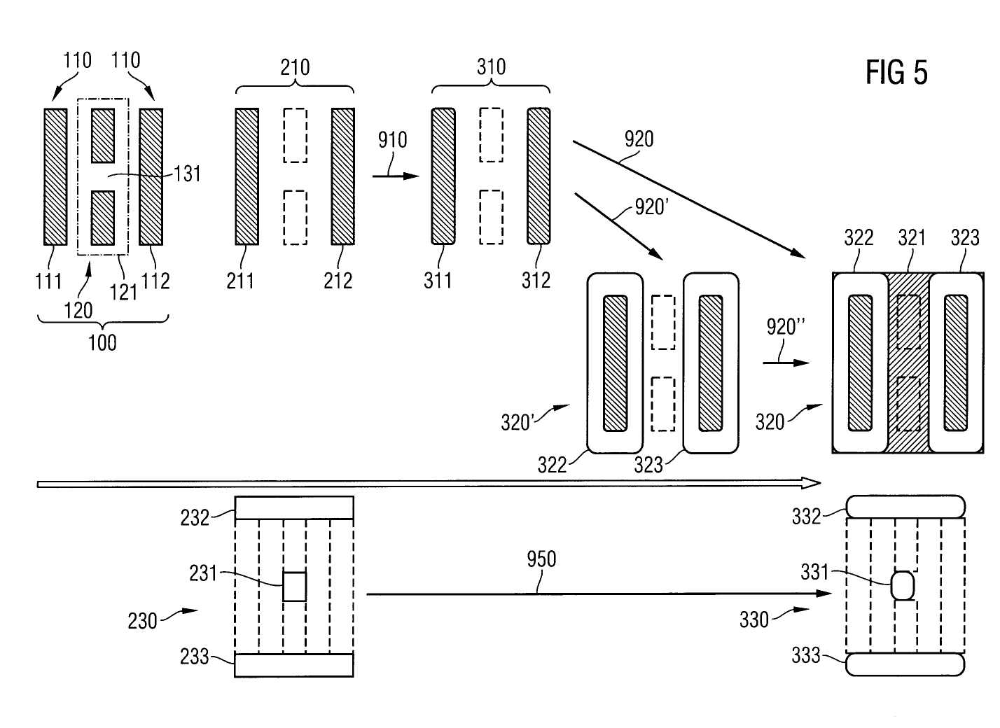

Subsequent figures illustrate the optimization method exemplarily by means of further layouts. For this, FIG. 5 shows a reference layout 100, which includes three line-shaped reference structures 111, 112, 121. While the two outer reference structures 111, 112, which are assigned to the first reference pattern 110, constitute continuous-line structures, the medium reference structure 121, which is assigned to a second reference pattern 120, is interrupted in its center by a hole structure 131. Also, in this example, the two outer reference structures 111, 112 represent e.g. two structures 711, 712 (FIG. 13) to be directly generated on the substrate 702 (see FIG. 13) as, for instance, two conductor structures. The middle reference structure 121 on the other hand represents an indirectly generated structure e.g. the structure 721 of FIG. 13, which is deduced from the two structures 711, 712 on the substrate 702, where the indirect structure 721, for instance, constitutes an active area consisting of two regions.

Initially, a first transfer pattern 210 shall be generated for the final model layout 500 e.g. a first photolithographic mask 601 (FIG. 11), by which means the structure information of the two transfer structures 211, 212 e.g. the two conductor structures 711, 712 (FIG. 13) is transferred directly to the substrate. For generation of the hole structure 131, 731, a second photolithographic mask 602 is used, which serves simultaneously as trim-mask for the self-adjusting process, which generates the second structure 721 corresponding to the second transfer structure 221.

As described in the prior embodiment in FIG. 5, the first transfer pattern 210 is transferred to a first image 310 by application of a first transfer function 910, which describes the changes of the two transfer structures 211, 212 resulting from the reference structures 111, 112 caused by the photolithographic imaging process. Subsequently, a second image 320 is generated by application of a second transfer function 920 to the first image 310, whereby the second image 320 is a preliminary stage of the second structure 721 (FIG. 13). The second transfer function 920 describes the process steps used for the deduction of the second transfer structure 221 respectively reference structure 121 e.g. the indirect structure 721 from the first reference structures 111, 112 respectively first transfer structures 211, 212 e.g. the two direct structures 711, 712.

In this embodiment, the method step 920 is also divided into two sub steps 920′ and 920″ for illustration of the method. At the first sub step 920′, the two auxiliary structures 322, 323 are generated, for instance by deposition of a material, which define a given distance to the images of the transfer structures 211, 212 e.g. the two conductor structures 711, 712. At the second sub step 920″, an elongated structure 321 is generated, for instance by deposition of a further material and thereby resulting fill of the trench between the two auxiliary structures 322, 323, whereby the elongated structure 321 constitutes a preliminary stage of the second structure 721 (FIG. 13).

As already mentioned, the generation of the hole structure 731 is done with the help of a second photo mask 602. For this, a second transfer pattern 230 is provided. The second transfer pattern 230 may, for instance, also be derived from the reference layout 100. It includes a third transfer structure 231, which represents the hole structure 731 and also two further transfer structures 232, 233, which serve as trim-structures for the generation of the second structure 721 shown in FIG. 13. The simulation of the third transfer structure 231, e.g. resulting into the hole structure 731 in this example is done in parallel to the simulation of the two first transfer structures 211, 212, leading to the structures 711, 712, whereby the second transfer pattern 230 is transferred to a third image 330 by application of a fifth transfer function 950. The final transfer function 930 thereby describes e.g. those changes to the transfer pattern 230 originated by the photolithographic imaging process. Because of diffraction effects for instance, the image structures 331, 332, 333 of the third image 330 show for instance rounded edges.

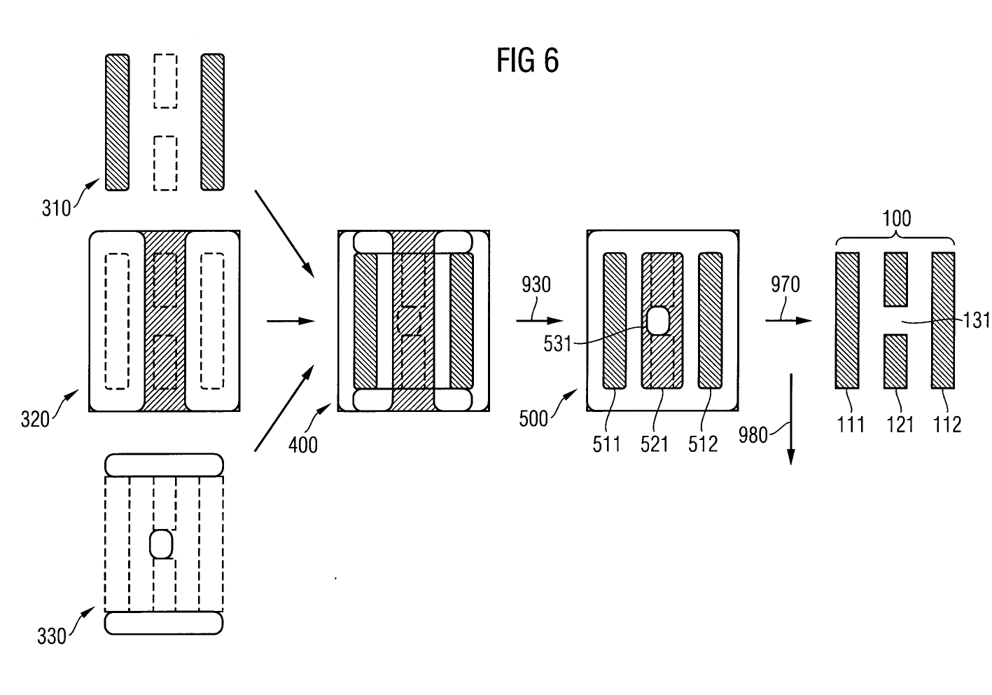

Next, an overall image 400 is generated by combination of the three images 310, 320, 330. This is shown in FIG. 6. Thereby, the images are superimposed in such a way that the third (hole) image structure 331 is now above the temporary image structure 321. The overall image 400 is finally transferred into the final model layout 500 which may be a new candidate model layout 500 by application of a final transfer function 930. Thereby, the middle structure 321 is trimmed in such way by the trim structures 332, 333 that three model structures 511, 512, 521 are generated, which are essentially of the same length.

The candidate for the model layout 500, which is generated in such a way, is subsequently compared to the original reference layout 100 to determine the deviation of the generated model structures 511, 512, 521, which are generated by simulation, with the predefined reference structures 111, 112, 121. It results that also in this example, the second model structure 521 deviates strongly from the second reference structure 121, whereby the first structures 511, 512 are satisfactorily formed to a large extent. In contrast to the second reference structure 121, the second model structure 521 is noticeably broader than the two outer model structures 511, 512. Due to their breadth as well as an alignment error, which results from the generation of the hole structure, the second model structure 521 is further on not completely divided by the hole image structure 331. Thus, the second model structure 521 deviates noticeably from the second reference structure 121.

Because also in the current example the even distribution of the deviation error across the whole layout is an important quality characteristic, the candidate model layout 500, which is generated during the first run of the simulation, fails to pass validation included in the validation process 900. That means that neither on of both current transfer patterns 210, 230 gives satisfactory results. Because of this, both transfer patterns 210, 230 of the current case undergo an optimization.

FIG. 7 shows the two transfer patterns 210, 230 after the optimization. Thereby, the two outer transfer structures 211, 212 of the first transfer pattern 210 were remarkably broadened. To make sure that e.g. the second structure 721 (FIG. 13) later on is completely divided, the hole transfer structure 231 of the second transfer pattern 230 was also broadened. To verify to what extent the correction undertaken of the transfer structures 211, 212, 231 improve the overall result, another candidate for the model layout 500 is generated in the second simulation run by means of both modified transfer patterns 210, 230. For this, the first transfer function 910 is applied to the modified first transfer structures 211, 212 to generate a modified first image 310. In parallel, the fifth transfer function 950 is applied to the optimized second transfer pattern 230 to achieve a modified third image 330. Further on, a modified second image 320 is generated by application of the second transfer function 920 to the first image 310. As shown in FIG. 7, the breadth of the preliminary structure 321 is now remarkably smaller due to the broader transfer structures 211, 212.

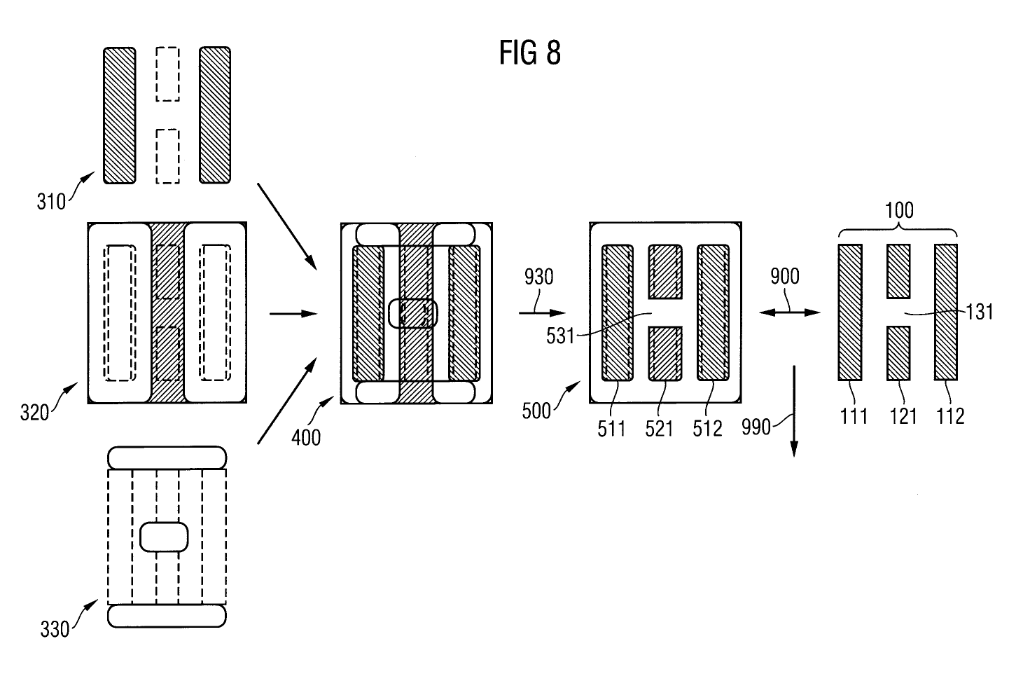

As shown in FIG. 8, an overall image 400 of the structure is established by a combination of three modified images 310, 320, 330. By application of the third transfer function 930, this combination 400 is finally transferred into the new candidate model layout 500. In distinction to the model layout 500 of the first simulation run, the three generated model structures 511, 512, 521 now show essentially the same breadth. Further on, the second model structure 521 is now completely divided by the broader hole structure 531. Because the deviation error is essentially equally distributed throughout the whole model layout 500 and also none of the model structures 511, 512, 521, 531 shows a deviation from the reference structures 111, 112, 121, 131 outside the respective tolerances, the optimization goal is reached. The following repeated validation of the new candidate model layout 500 therefore leads to a finalization of the optimization. The two optimized transfer layouts 210, 230 may be handed over to the mask manufacturing.

It is not absolutely necessary to optimize the two transfer patterns 210, 230. If and how far a transfer pattern 210, 230 is modified before a repeated simulation run, may be dependent on which modification of the respective other transfer pattern at this stage of the optimization should be done. For instance it may make sense to modify the first transfer pattern 210 only marginally or not at all before running a repeated simulation, if it can be foreseen that the modification of the second transfer pattern 230 leads to a better overall result as a modification of the first transfer pattern 210. Depending on the application, only specific transfer patterns, respectively transfer structures, may be specifically modified in the different optimization runs in order to better assess the effect of these modifications to the overall result. To what extent such single optimization is executed may be dependent on the computing power or the computing time, respectively, available for the overall optimization process.

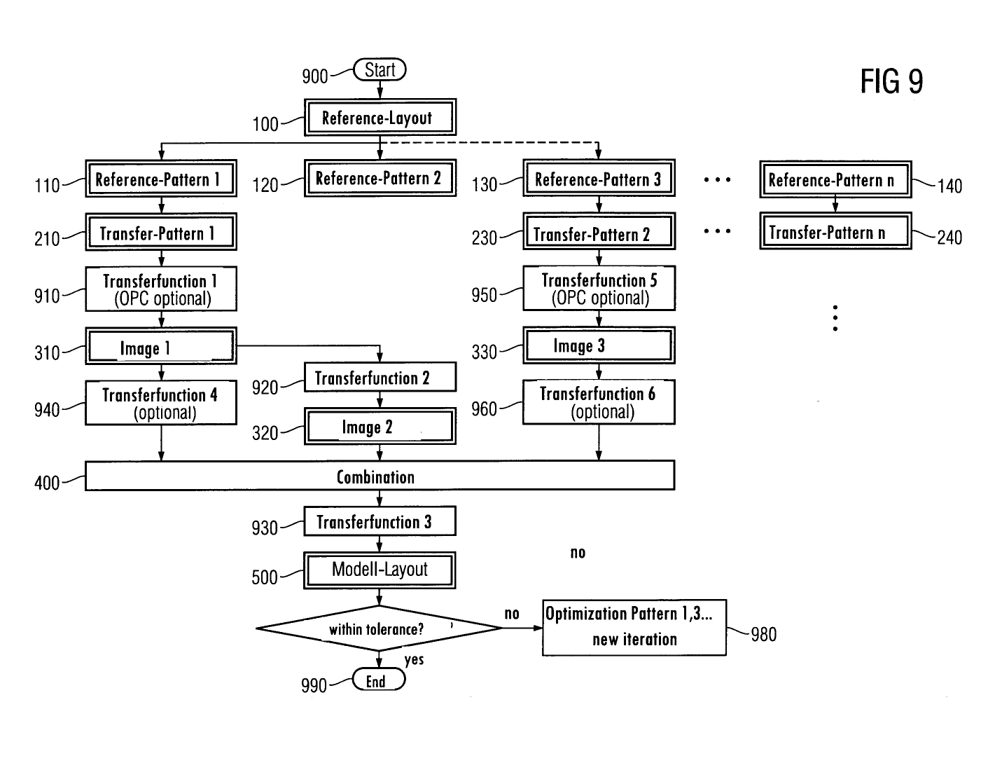

FIG. 9 shows a flow diagram of the method for optimization of the transfer patterns 210, 230, 240 of at least one transfer device 601, 602. At the beginning 900 of the optimization process a reference layout 100 is provided, which includes at least a first and a second reference pattern 110, 120. The first reference pattern 110 includes at least a first reference structure 111, 112, which is a reference for a further microstructure 111, 112 to be generated on the substrate 702 in the real manufacturing process. On the other hand, the second reference pattern 120 includes at least a second reference structure 121, which is the reference for an indirect second microstructure 721 to be generated on the substrate by deduction from the first microstructure 711, 712 in the real manufacturing process. Contrary to the structures 111, 112 of the first reference pattern 110, whose structure information is directly transferred by means of a transfer device 601, 603 to the substrate, the second structure 721 associated to the second reference pattern 120 evolves only by deduction of at least one directly generated structure 711, 712, 731.

Firstly, the respective transfer patterns 210, 230, 240 are generated by means of the reference patterns 110, 130, 140 formed from the reference layout 100 provided. At the first circle of the optimization method, the original reference patterns may be used as transfer pattern. It is also possible to use transfer patterns already at the beginning of the optimization method, which already have modifications in respect to the reference patterns. This may be useful for instance, if it can be foreseen that specific transfer structures or transfer patterns, respectively, for instance due to the fragmentation of the reference layout 100 into the single reference patterns 110, 120, 130, does not lead to the required result.

Now the real manufacturing process is reproduced sufficiently precise for each of the directly and indirectly generated structures 711, 712, 721, 731 by means of a transfer pattern 210, 230 to generate model structures 511, 512, 521, 531 (FIG. 6) according to the respective structures 711, 712, 721, 731 (FIG. 13). By means of these model structures shall be decided whether an optimization of the respective transfer patterns 210, 230 is necessary to get a preferably good fit of the structures generated thereby with the respective reference structures.

For this, the first transfer pattern 210 is transferred to a first image by application of a first transfer function 910. The first transfer function 910 thereby describes the changes of the first transfer structures 211, 212 caused by the transfer of the first transfer pattern 210 to the substrate 702. Therefore, the first image 310 in a photolithographic process represents the structures 711, 712, which were generated in the substrate 702 after the optical imaging of the first transfer pattern 210 in the photo layer or after further process steps, respectively. Subsequently, a second image 320 is generated by application of a second transfer function 920 to the first image 310, whereby the second image 320 corresponds to the second structure 721, which is deduced from the first structures 711, 712 directly generated on the substrate.

The images 310, 320 are subsequently combined with each other in order to form an overall image 400. Subsequently, a final transfer function 930 accounts for changes of the structures, which result from combination or further processing, respectively, of the overall structure. By application of the final transfer function 930, the final model layout 500 is generated.

In the following method step 970, the generated candidate model layout 500 is compared to the reference layout 100 and by means of the comparison result, it is decided whether the optimization method will be finalized or whether a further optimization step 980 is necessary. If an optimization step is necessary, the respective transfer pattern 210, 230 is optimized and subsequently, a respective modified candidate model layout 500 is generated by a reiterated emulation of the manufacturing process.

As indicated in FIG. 9, corrections of an optical proximity correction OPC method can be already taken into account in the method steps 910, 950. Basically, such corrections may be made also independently from the optimization method described here. For instance, an OPC method can be conducted after the optimization of the mask pattern 210, 230. Because the results of such a correction may influence the optimization described here and vice versa, it is recommended to conduct the respective corrections in the framework of the optimization method according to an embodiment of the invention.

As is also shown in FIG. 9, a fourth transfer function can be applied to the first image 310 and a sixth transfer function 960 can be applied to the third image, in order to take into account changes of the structures 711, 712, 731, which may occur during the processing.

Further, the reference layout 100 may also include a third reference pattern 130 with a third reference structure 131 (e.g. FIGS. 5 and 7), which serves as a master for a third structure 731 to be directly generated on the substrate analogous to the first structure 711, 712, whereby the generation of the second structure 121 also results by deduction from the third structure 731 on the substrate 702. Thereby, the third reference pattern 130 is used as master for a second transfer pattern 230, that includes a third transfer structure 231 corresponding to a third reference structure 131. By transferring the third transfer structure 231 to the substrate 702, the third structure 731 is directly generated. By application of a fifth transfer function 950, the third transfer pattern 230 is transferred into a third image, which is combined with a first and a second image 310, 320 to achieve the overall image 400.

As it is shown especially in FIG. 9 and its description, it is the goal of the embodiment presented here to describe all the single parts of the overall layout including the directly and indirectly imaged structures by their assigned transfer functions and to combine them according to the process conduct, so that a description of the expected final state is obtained. If the final state deviates too much from the reference layout, the individual parts shall be iteratively optimized until the calculated end status is sufficiently close to the original layout.

FIG. 10 shows a first transfer device 601 for generation of the two first structures 711, 712 (FIG. 13) on the substrate. In this case, the first transfer device 601 is established as a photo mask. It includes two mask structures 611, 612, which were generated by the overlay of the optimized transfer structures 211, 212 from FIG. 5-8 to a structure layer 604, which is placed on a carrier structure 603.

FIG. 11 shows the first transfer facility 601 in an alternative embodiment. In contrast to the alternative shown in FIG. 10, here, the two transfer structures 211, 212 resulting in structures 611, 612 are shown realized as elevation on the carrier structure 603. The transfer device 601 shown in FIG. 11 may e.g. be a negative bright-dark mask. Additionally, the transfer device 601 may also be produced for a different manufacturing method, as for instance as a punch for the soft-print method.

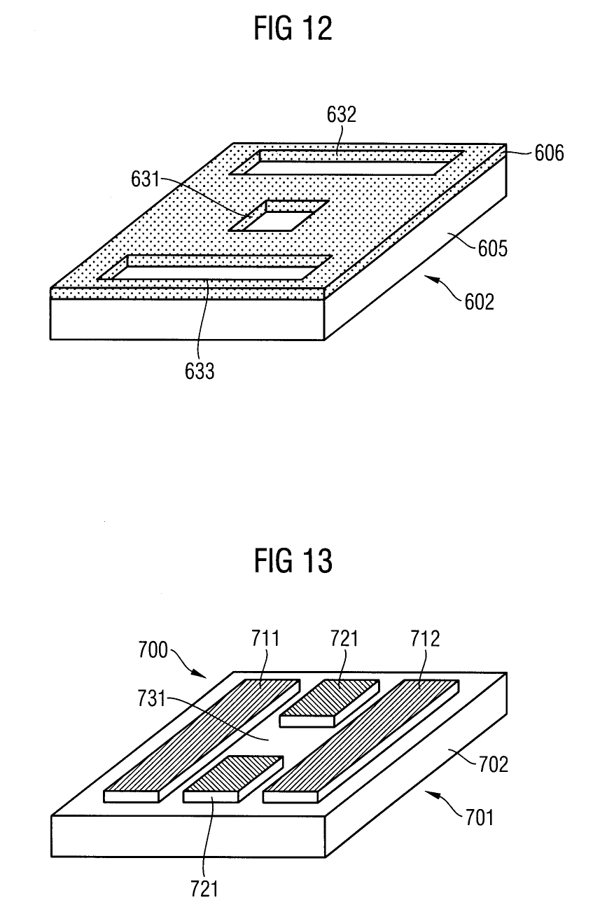

FIG. 12 shows a second transfer device 602 for generation of the third structure 731 as well as the two trim structures on the substrate. Also, the second transfer device 602 in this case is established as a photo mask and includes three mask structures 631, 632, 633, which were generated by transfer of the optimized transfer structures 231, 232, 233 from FIG. 5-8 in a structure layer 606, which is placed on a carrier structure 605.

Depending on the application, each of the transfer facilities 601, 602 shown here may be established as a lithographic mask, as for instance a bright-dark mask or a phase-shift mask. Further on, the transfer facilities 601, 602 may also be established for production of structures by means of a different structuring method, as for instance a soft-print method. It is also possible to establish the respective transfer structures directly within the carrier structure 603, 605 itself, and not in a separate carrier layer 604, 606 as shown in FIG. 10-12. In a direct imaging method, as for instance the electron-beam direct-writing, the respective transfer structures can also be used as input for the respective facilities for writing the structures to the substrate.

FIG. 13 shows as an example substrate 702 with directly and indirectly generated structures 711, 712, 721. The generation of the structures 711, 712, 721 took place by means of the two transfer facilities 601, 602, whose transfer pattern 210, 230 were optimized by the method as described before. The end product 701, which is shown in FIG. 10, may for instance be a microchip including an integrated circuit, which is arranged on a semiconductor substrate 702.

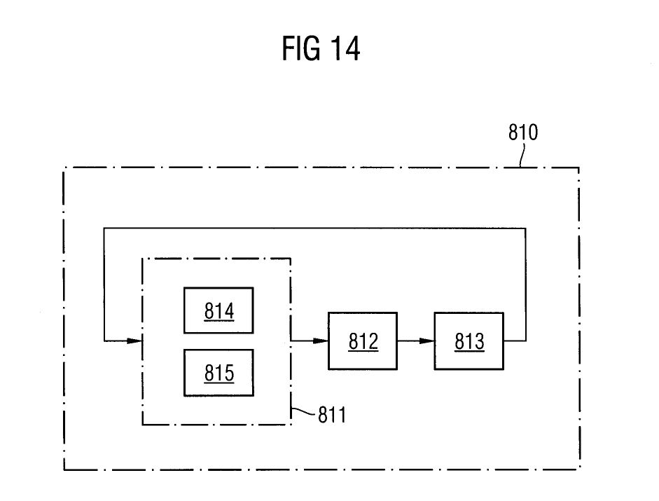

FIG. 14 shows the fundamental composition of an device 810 for optimization of the transfer pattern 210, 230 generated by means of the reference layout 100. The device 810 generates at least a transfer pattern 210, 230 by means of the reference pattern 100 and conducts an optimization of the individual transfer pattern 210, 230 by means of the optimization method described above to ensure a preferably optimal image of the structure 711, 712, 721, 731 in a subsequent photolithographic imaging process. For this, the optimization device 810 includes a process emulation circuitry 811, a validation circuitry 812, and an optimization circuitry 813. The process emulation circuitry 811 emulates the manufacturing process of the structures 711, 712, 721, 731 on the substrate and thereby generates a candidate for the model layout 500 with model structures 511, 512, 521, 531, which correspond to the structures 711, 712, 721, 731 generated on the substrate. The generation of the candidate model layout 500 may thereby take place by means of the simulation facility 814, that, starting from a physical model of the structures simulates the manufacturing process step by step. The result of this simulation is a realistic model of the structures 711, 712, 721, 731, which are generated on the substrate by means of the transfer patterns 210, 230 considered.

Further on, the candidates for the model layout 500 or parts thereof can be generated also by means of the control circuitry 815, that, starting from the geometric properties of the structures, by application of simple rules simulates the changes, which occur to the structures or the transfer structures, respectively, during the manufacturing process. The applied rules are typically based on experienced values, how specific structures or patterns, respectively, are changed in individual process steps or in the overall process, respectively. The process emulation carried out by means of the control circuitry 815 typically results in a relatively rough model of the structures 711, 712, 721, 731, which are generated on the substrate by means of the considered transfer patterns 210, 230.

Because at the process simulation the physical or the chemical processes, respectively, during the generation of the structures are reproduced preferably precisely the simulation circuitry 814 requires remarkably more computing time or computing power, respectively, than the process emulation by means of the control circuitry 815.

The process emulation circuitry 811 shown in FIG. 14, may also be combined with other methods. For instance, relative simple model structures of a model layout 500 can be generated by means of the control circuitry 814, whereby for the generation of complicated model structures of the model layout 500, the process simulation is used.

The process emulation circuitry 811 may describe the manufacturing process of single structures or full sets of structures by means of transfer functions, which correspond to single process steps or several combined process steps, respectively. By application of this transfer functions to single transfer structures or transfer patterns, images of the respective structures or patterns, respectively, are generated, which can be successively be combined to a final model layout 500. Subsequently, the process emulation circuitry 811 hands over the finalized model layout 500 to the validation circuitry. The comparison of the candidate model layout 500 to the original reference layout 100 takes place here. If the validation circuitry 812 detects a deviation of the model structures 511, 512, 521, 531 from the respective reference structures 111, 112, 121, 13, which exceeds specified tolerance values, an optimization of the transfer pattern 210, 230 corresponding to the method described above is triggered in the optimization facility 813. Depending on the application, the transfer patterns 210, 230 and the transfer structures 211, 212, 221, 231 may be modified individually as well as together. The optimization circuitry 813 hands over the optimized transfer patterns 210, 230 with the modified or corrected, respectively, transfer structures 211, 212, 221, 231 again to the process emulation circuitry 811, which generates a modified model layout 500 by means of this data.

If the validation circuitry 812 does not identify a significant deviation at the current candidate model layout 500 in respect to the reference layout 100, it may finalize the optimization process.

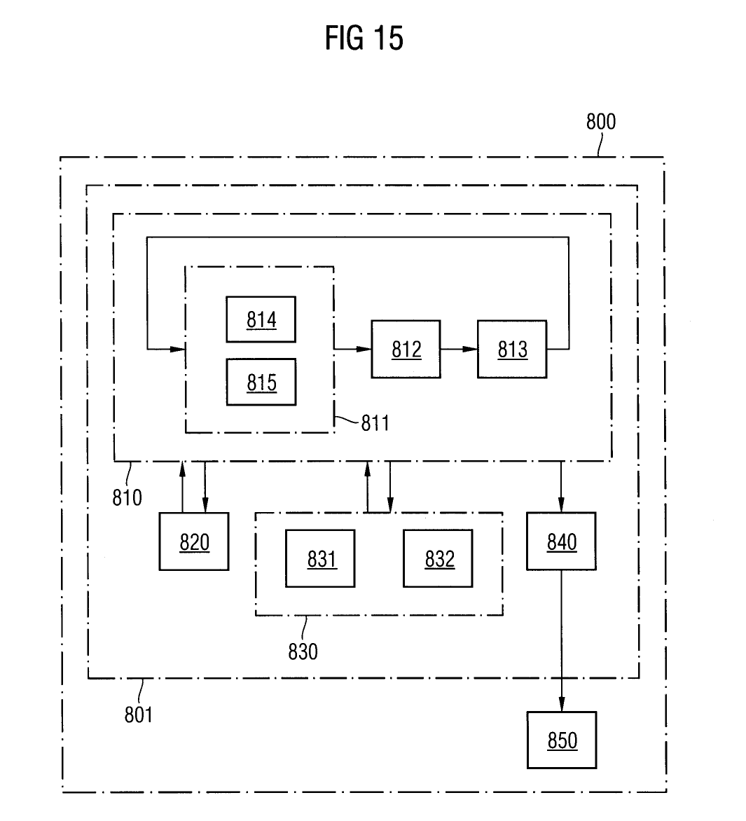

It is possible to configure the optimization circuitry 810 in such a way that the optimization of the transfer pattern is finalized if the predefined criteria as for instance an equal distribution of the deviation error cannot be reached even after several cycles. On the one hand, this may happen if it is detected that an additional optimization cycle does not achieve an improvement in respect to the specification. On the other hand, canceling of the optimization of the transfer pattern can take place automatically for instance after a predefined number of cycles or after a predefined time. In case that no or only an insufficient optimization result is found, the optimization circuitry 810 may give a reply to the model circuitry 820 (see FIG. 15), that with the given layout or with the chosen process control, respectively, no satisfactory solution can be achieved. Thereby, those positions of the respective structures may be communicated, for which with the predefined conditions there is not achieved a satisfactory solution. Thus, it can be examined with the help of the optimization circuitry 810 described here or by means of the optimization method described here, respectively, in how far the required structures can be realized with the predefined process control by means of the given starting layout.

Typically, the apparatus 810 includes at least a computing unit to carry out the calculations necessary for the process emulation, the validation and/or the optimization. Each of the circuitries 811, 812, 813 may also be realized in form of a software module, that runs on a computing unit. Further on, also multiple computing units may be used for performing the optimization method, especially in such a case if relative complex structures or process steps are intended. In such a case, also individual process sequences of an optimization cycle may be emulated on a separate computing unit. So it may be for instance advantageous for special calculation intensive method steps to use a special calculation unit configured for this purpose.

FIG. 15 shows the basic configuration of a system 800 for manufacturing of transfer devices 601, 602, by which structures 711, 712, 721, 731 are generated on a substrate 702 according to the target settings of a reference layout 100. The system 800 includes a model circuitry 820 for generation of the reference layout 100, a circuitry 810 for optimization of transfer pattern 210, 230, as shown in FIG. 14, as well as a manufacturing circuitry 850 for generation of the transfer circuitries 601, 602 with the optimized transfer pattern 210, 230. The model circuitry 820 generates the reference layout 100 by means of design specifications. This is done by conventional model processes which will not be discussed in further detail here. After the finalization of the reference layout 100, it is provided to the optimization circuitry 810. The optimization circuitry 810 finally hands over the transfer patterns 210, 230 after the optimization to the manufacturing circuitry 850, which transfers each transfer pattern to the respective carrier substrate to generate an optimized transfer circuitry 601, 602. In case of a photo mask, this can be done for instance by means of a typical mask writer. Before the hand-over of the optimized transfer patterns 210, 230 to the manufacturing circuitry 850, the data of the transfer pattern of this embodiment are stored in a special transfer circuitry 840 of the arrangement 801. This transfer facility 840 finally provides the data to the manufacturing circuitry 850.

During the generation of the model structures 511, 512, 521, 531, but also during the optimization of the transfer patterns 210, 230, it may be useful to access specific data. These may be provided from an external data storage circuitry 830, as shown in FIG. 11, to which the respective circuitries 811, 812, 813 can access. However, it is also possible that at least part of the data is stored on an internal database of the apparatus or the respective circuitry 811, 812, 813, respectively, which are not shown here.

As shown in the prior description, the correction of the directly transferred parts of an initial layout is optimized in such a way that in average the smallest deviation for directly and indirectly generated structures is originated. Further on, it is intended by the method described here to describe a manufacturing of each individual layout part by one or multiple transfer functions beyond the mere addition of intensities. Thereby, also the form of the final sum of the structures on the substrate may be calculated. Based thereon, the individual layout parts can be optimized in an iterative method in such a way that the sum of the imaged parts is sufficiently close to the initial, respectively original layout. By this, it is possible to image also complex structures with double-patterning methods.

Despite the invention being described as an optimization method for photo masks in this description, the invention is not limited to photolithographic imaging processes. On the contrary, the invention can also be used for other manufacturing processes as for instance the so-called soft lithography, respectively soft-print method, for which a punch is used as transfer facility. Further on, the method described here can also be used for the optimization, respectively verification of layout for manufacturing methods, for which the structures are directly written to the substrate, respectively into a layer of the substrate as for instance the electron-beam lithography. For this manufacturing method, the layout structures are transferred to the substrate by means of a special electron-beam direct writer. Further examples for such direct writing manufacturing methods are the ion lithography, the laser lithography, and similar methods.

While in the embodiments of the invention described above a preferably even distribution of the deviation error across all structures of the layout is intended, in other cases an uneven distribution of errors may be desired. Therefore, specific structures of the layout are optimized at the cost of other structures of the layout. For instance the dimensional accuracy of a contact region, for which any deviation is critical, can be improved by diminishing the dimensional accuracy of a conductor structure, for which the deviation is less critical. The respective error distribution can be described by means of a cost function. For instance this can be also achieved by choosing a bigger tolerance for less critical parts of the structure than for critical parts of the structure.

Embodiments of the invention are, for example:

A method 1 for generation of an optimized transfer pattern for at least one transfer device, by which means structures are generated from requirements of a reference layout, wherein the reference layout includes a first reference pattern with a first reference structure, which serves as a requirement for a structure to be directly generated on the substrate, wherein by means of the first reference pattern a first transfer pattern for a first transfer facility is generated, which is dedicated to the transfer of the first transfer pattern to the substrate for the direct generation of the first structure, wherein the reference layout includes a second reference pattern with a second reference structure, which serves as a requirement for a second structure to be indirectly generated on the substrate by deduction from the first structure, whereby the first transfer pattern is optimized to that effect that a deviation of the first structure from the first reference structure is reduced, and wherein the first transfer pattern is also optimized to that effect that a deviation of the second structure from the second reference structure is reduced.

A method 2 is method 1, wherein the generation of the second structure includes a combination of the first and a third structure, wherein a second transfer pattern for a second transfer facility for generation of the third structure on the substrate is used, and wherein also the second transfer pattern is optimized to that effect that the deviation of the second structure from the second reference structure is reduced.

A method 3 is method 2, wherein the second transfer pattern is optimized to that effect that the deviation of the first structure from the first reference structure is reduced.

A method 4 is method 2, wherein the reference layout includes a third reference pattern with a third reference structure, which serves as requirement for the third structure, and wherein the third reference pattern is used as master for the second transfer pattern.

A method 5 is method 1, wherein the optimization of the transfer pattern is computer-aided and includes the following steps:

a) application of a first transfer function to the first transfer pattern to generate a first image,

b) application of a second transfer function to the first image to generate a second image,

c) generation of a first and a second model structure including model layouts from the first and the second image,

d) comparison of the first model structure with the first reference structure and the second model structure with the second reference structure,

e) correction of the first transfer pattern and repeating of method steps a) to d) if in method step d) at least one of the two model structures a deviation from the respective reference structure is determined, which is outside a predetermined tolerance range, and

f) finalization of the optimization of the first transfer pattern as soon as in method step d) the determined deviation between the model structure and the respective reference structure is within the tolerance.

A method 6 is method 5, whereby the generation of the model layout in method step c) includes a combination of the first and the second image.

A method 7 is method 6, wherein the generation of the model layout in method step c) further includes usage of a third transfer function to the combination of the first and the second image.

A method 8 is method 7, wherein a fifth transfer function is applied to the second transfer pattern to generate a third image, and wherein for generation of the model layout in method step c) the third image is combined with the first and the second image and the third transfer function is applied to this combination.

A method 9 is method 7, wherein in method step e) also the second transfer pattern is corrected if in method step d) a deviation of the second model structure from the second reference structure is examined, which is outside of the tolerance.

A method 10 is method 6, wherein a fourth transfer function is applied to the first image before the combination of the images is made.

A method 11 is method 5, wherein the optimization of the transfer pattern takes place iteratively, and wherein at one iteration step at least one of the transfer patterns is corrected in such a way that at least one of the model structures generated by its means the deviation from the respective reference structure is reduced.

A method 12 is method 5, whereby the model layout is generated by simulation of the manufacturing process of the structures and/or by means of experienced is emulated.

A method 13 is method 1, wherein at least one of the transfer patterns is optimized as pattern for a photolithographic mask for transfer of the transfer pattern to the substrate.

A method 14 is method 13, wherein at least one of the transfer patterns is corrected by means of an OPC method.

A method 15 is method 13, wherein each of the transfer patterns is optimized to that effect that for all model structures generated directly and indirectly thereby the averaged smallest deviation from the reference structures is achieved.

A method 16 is method 13, wherein the optimization of the transfer pattern takes place in the framework a double-patterning or a pitch-fragmentation method.

A method 17 is method 1, wherein the optimization of the transfer pattern after a predefined number of optimization cycles or after a predefined time is stopped.

A method for manufacturing a photolithographic mask, wherein a transfer pattern is generated by means of a reference pattern, wherein the transfer pattern is optimized by means of a method according to one of the method 1, and wherein the optimized transfer pattern subsequently is transferred to a carrier structure of the photolithographic mask.

An device 1 to carry out the method 1, including a process emulation circuitry, a comparison circuitry, and an optimization circuitry, wherein the process emulation circuitry is configured to generate a model layout by application of a transfer function to the first transfer pattern, wherein the comparison circuitry is configures to compare the model structures of the model layout with the respective reference structures, wherein the optimization circuitry is configured to optimize the first transfer pattern to that effect that the deviation of the first structure from the first reference structure is reduced, and wherein the optimization circuitry is further configured to optimize the first transfer pattern also to that effect that the deviation of the second structure from the second reference structure is reduced.

A device 2 is device 1, wherein the process emulation circuitry is configured to generate the model layout by application of transfer functions to the first and the second transfer pattern, and wherein the optimization facility is further configured to optimize also the second transfer pattern to that effect that the deviation of the second structure from the second reference structure is reduced.

An device 3 is device 2, wherein the process emulation facility includes a simulation arrangement to generate the model layout by simulation of the manufacturing process of the structures by means of the transfer pattern.

An device 4 is device 2, wherein the process emulation circuitry includes a control arrangement to generate the model layout by emulation of the manufacturing process of the structures of the transfer pattern by means of experienced data.

A system 1 for manufacturing at least one transfer device, includes:

a model circuitry to generate a reference layout,

a circuitry according to the device 1 to optimize a transfer pattern generated according to the requirement of a reference layout,

a data storage circuitry for providing data for the process emulation circuitry, the comparison circuitry and/or the optimization circuitry of the apparatus, and

a manufacturing circuitry for generation of the transfer device with the optimized transfer pattern.

A system 2 is system 1, whereby the optimization circuitry is configured to send a reply to the model circuitry if no solution according to the requirements is achieved with the predefined model layout.

A data carrier 1 is a data carrier with a program to carry out a method 1.

A device for generating a model layout for the manufacturing of a transfer device, the model layout having a first model structure and a second model structure, the device having:

a first generating circuitry configured to generate a first image from a first transfer structure using a first transfer function, wherein the first transfer function comprises characteristics of a direct manufacturing process, wherein the first transfer structure is associated with a first reference structure, and wherein the first transfer structure represents a structure to be directly generated on the substrate using a direct manufacturing process;
a second generating circuit configured to generate a second image from the first image using a second transfer function, wherein the second transfer function comprises characteristics of an indirect manufacturing process, wherein the second transfer structure is associated with a second reference structure, wherein the second transfer structure represents a structure to be indirectly generated on the substrate using an indirect manufacturing process;
a combining circuit configured to combine the first image and the second image, thereby generating a candidate model layout comprising a first candidate model structure and a second candidate model structure;
a determination circuit configured to determine as to whether the candidate model layout fulfills a predefined criterion, wherein the determination circuit is further configured to define the candidate model layout as the model layout in case the predefined criterion is fulfilled.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for generating a model layout for the manufacturing of a transfer device, the model layout comprising a first model structure and a second model structure, the method comprising:
a) providing a first transfer structure and a second transfer structure, wherein the first transfer structure is associated with a first reference structure, and wherein the second transfer structure is associated with a second reference structure;
b) wherein the first transfer structure represents a structure to be directly generated on the substrate using a direct manufacturing process, and wherein the second transfer structure represents a structure to be indirectly generated on the substrate using an indirect manufacturing process;
c) generating a first image from the first transfer structure using a first transfer function, wherein the first transfer function comprises characteristics of the direct manufacturing process;
d) generating a second image from the first image using a second transfer function, wherein the second transfer function comprises characteristics of the indirect manufacturing process;
e) combining the first image and the second image, thereby generating a candidate model layout comprising a first candidate model structure and a second candidate model structure;
f) determining as to whether the candidate model layout fulfills a predefined criterion; and
g) using the candidate model layout as the model layout in case the predefined criterion is fulfilled.

2. The method of claim 1, further comprising:
changing at least one of the first transfer structure and the second transfer structure if it has been determined that the candidate model layout does not fulfill the predefined criterion; and
repeating c) to g) using the changed transfer structure.

3. The method of claim 1,
wherein determining as to whether the candidate model layout fulfils a predefined criterion comprises determining as to whether the first candidate model structure and the second candidate model structure are sufficiently similar to a first reference structure and a second reference structure.

4. The method of claim 3,
wherein determining as to whether the candidate model layout fulfils a predefined criterion comprises determining as to whether a distribution of the deviation error of the first candidate model structure and the second candidate model structure with respect to the first reference structure and the second reference structure is smaller than a predefined threshold.

5. The method of claim 1, further comprising:
providing a third transfer structure;
generating a third image from the third transfer structure using a third transfer function, wherein the third transfer function comprises characteristics of a first manufacturing process;
wherein the combination further comprises combination the third image.

6. The method of claim 1, further comprising:
generating a final image from the combined first and second images using a final transfer function, thereby generating the candidate model layout, wherein the final transfer function comprises characteristics of a second manufacturing process.

7. The method of claim 1,
wherein the transfer device is configured as a photolithographic mask.

8. The method of claim 1,
wherein the indirect manufacturing process comprises at least one of a double patterning process and a pitch fragmentation process.

9. The method of claim 2,
wherein the repetition of the method is stopped after at least one of a predefined number of already performed repetitions or an expiration of a predefined time period.

10. A method for manufacturing a transfer device, comprising:
providing a first transfer structure and a second transfer structure, wherein the first transfer structure is associated with a first reference structure, and wherein the second transfer structure is associated with a second reference structure;
wherein the first transfer structure represents a structure to be directly generated on the substrate, and wherein the second transfer structure represents a structure to be indirectly generated on the substrate;
generating a first image from the first transfer structure using a first transfer function, wherein the first transfer function comprises characteristics of a direct manufacturing process;
generating a second image from the first image using a second transfer function, wherein the second transfer function comprises characteristics of an indirect manufacturing process;
combining the first image and the second image, thereby generating a candidate model layout comprising a first candidate model structure and a second candidate model structure;
determining as to whether the candidate model layout fulfills a predefined criterion;
using the candidate model layout as the model layout in case the predefined criterion is fulfilled; and
manufacturing the transfer device using the model layout.

11. The method of claim 10,
wherein the transfer device is manufactured as a photolithographic mask.
